(19) United States
(12) Patent Application Publication
(10) Pub. No.: US 2007/0043523 A1
(43) Pub. Date: Feb. 22, 2007

(54) System and method for inspecting pictures of a liquid crystal display

(75) Inventors: Jing-Zhou Lai, Shenzhen (CN); Tong-Xiu Cao, Shenzhen (CN); Kuang-Liang Huang, Miaoli (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/507,262

(22) Filed: Aug. 21, 2006

(30) Foreign Application Priority Data
Aug. 19, 2005 (CN) 200510036760.9

(51) Int. Cl. G01R 13/02

(52) U.S. Cl. 702/67; 702/82

(57) ABSTRACT

An exemplary system for inspecting pictures of a liquid crystal display (LCD) (20) is provided. The system is configured in a host computer (10) that stores standard parameters of pictures for display by the LCD. The system includes: a setting module (13) configuring for setting one or more parameters of the pictures and a video card, and for generating corresponding signals according to the set parameters, the set parameters being for one or more function inspections of the LCD; a transmitting module (15) configuring for transmitting the signals to the LCD so that the LCD can process the signals and display corresponding pictures; a determining module (17) configuring for comparing actual parameters of the pictures actually displayed on the LCD with the standard parameters, and for determining whether the set parameters of the pictures and the video card are satisfactory according to a result of the comparison.

### BACKGROUND OF THE INVENTION

1. Field of the Invention

The present invention relates to systems and methods for inspecting electronically generated pictures, and more particularly to a system and method for inspecting pictures of a liquid crystal display (LCD).

2. Related Art

With the continued development of liquid crystal display (LCD) devices, these devices are being utilized in various new products. The standards of quality required of LCD devices are becoming more demanding. Reliability is an important criterion of quality, and various tests are provided specifically for testing the reliability of LCD devices. Such tests include high temperature, high humidity, and low temperature tests.

The display quality of an LCD is also important. In order to insure good picture quality of a display screen of an LCD, various systems and methods are provided to test the picture displaying quality of the LCD. In a traditional test method, a tester writes testing programs into a signal generator, and the signal generator generates corresponding signals. The LCD receives the signals and displays corresponding pictures. A camera gathers image-data of the pictures displayed on the screen of the LCD. The image-data are then compared to benchmark image-data. Thus, the displaying quality of the LCD can be determined. However, the signal generator is generally rather expensive. In addition, the other testing hardware tends to be complex, with various ancillary testing tools also being required.

What is needed, therefore, is a system and method for inspecting pictures displayed by an LCD simply and quickly.

### SUMMARY

A system for inspecting pictures of a liquid crystal display (LCD) is provided. The system is configured in a host computer. The host computer stores standard parameters of pictures for display by the LCD. The system includes a setting module, a transmitting module and a determining module. The setting module is configured for setting one or more parameters of the pictures and a video card, and for generating corresponding signals according to the set parameters, the set parameters being for one or more function inspections of the LCD. The transmitting module is configured for transmitting the signals to the LCD so that the LCD can process the signals and display corresponding pictures. The determining module is configured for comparing actual parameters of the pictures actually displayed on the LCD with the standard parameters, and for determining whether the set parameters of the pictures and the video card are satisfactory according to a result of the comparison.

A related method for inspecting pictures of the LCD includes: storing standard parameters of pictures for display by the LCD; setting one or more parameters of pictures for display by the LCD; setting one or more parameters of a video card; generating corresponding signals according to all the set parameters; transmitting the signals to the LCD so that the LCD can display corresponding pictures; generating actual parameters of the pictures actually displayed on the LCD; comparing the actual parameters of the pictures with the standard parameters; and determining whether the set parameters of the pictures are satisfactory according to the comparison result.

Other systems, methods, features, and advantages will be or become apparent to one with skill in the art upon reading the following detailed description and examining the accompanying drawings, in which:

### BRIEF DESCRIPTION OF THE DRAWINGS

FIG. 1 is a schematic diagram of hardware and software configuration of a system for inspecting pictures of a liquid crystal display (LCD) in accordance with one preferred embodiment of the present invention, together with an LCD, wherein the system is configured in a memory of a host computer;

FIG. 2 is a signal flow chart in respect of the system of FIG. 1;

FIG. 3 is a schematic diagram of software function modules of the system of FIG. 1; and

FIG. 4 is a flowchart of a method for inspecting pictures of an LCD in accordance with another preferred embodiment of the present invention.

### DETAILED DESCRIPTION OF THE EMBODIMENTS

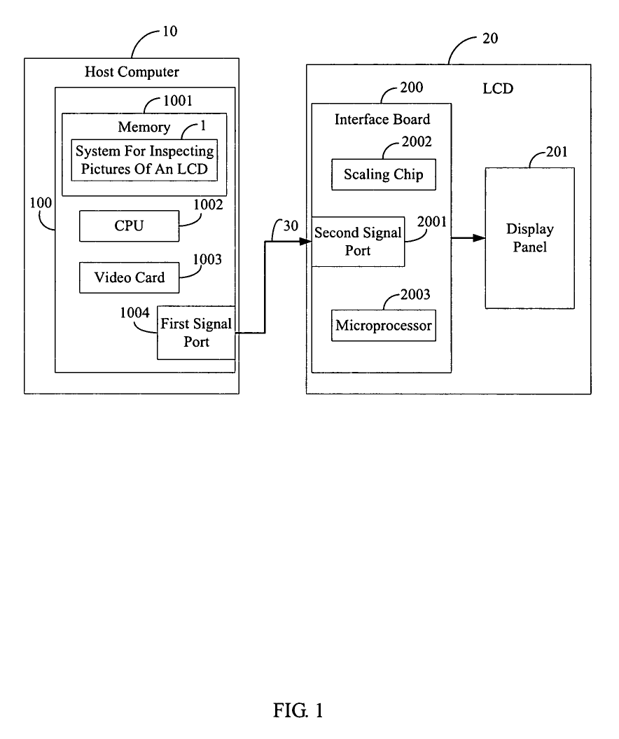

FIG. 1 is a schematic diagram of hardware and software configuration of a system for inspecting pictures of a liquid crystal display (LCD) (hereinafter, “the system 1”) in accordance with one preferred embodiment of the present invention, together with an LCD 20. The system 1 is configured in a memory 1001 of a host computer 10. The host computer 10 is connected with the LCD 20 via a signal line 30.

The host computer 10 includes a motherboard 100. The motherboard 100 mainly includes the memory 1001, a central processing unit (CPU) 1002, a video card 1003, and a first signal port 1004. The memory 1001 stores the system 1, which is configured for inspecting pictures of an LCD such as the LCD 20. The CPU 1002 is configured for controlling operations of the host computer 10, and for processing data of the system 1 in order to generate signals. The data include picture patterns, colors, and so on. The signals include sync signals and chrominance signals. The video card 1003 is configured for controlling conversion from one picture pattern on the LCD 20 to another picture pattern.

The LCD 20 mainly includes an interface board 200 and a display panel 201. The interface board 200 includes a second signal port 2001, a scaling chip 2002, and a microprocessor 2003. The second signal port 2001 is connected with the first signal port 1004 via the signal line 30. The second signal port 2001 and the first signal port 1004 can be video graphics assembly (VGA) ports. The scaling chip 2002 is configured for processing the signals. In the preferred embodiment, the microprocessor 2003 is external to the scaling chip 2002. In an alternative embodiment, the microprocessor 2003 can be incorporated in the scaling chip 2002. The display panel 201 is configured for displaying the signals as pictures.

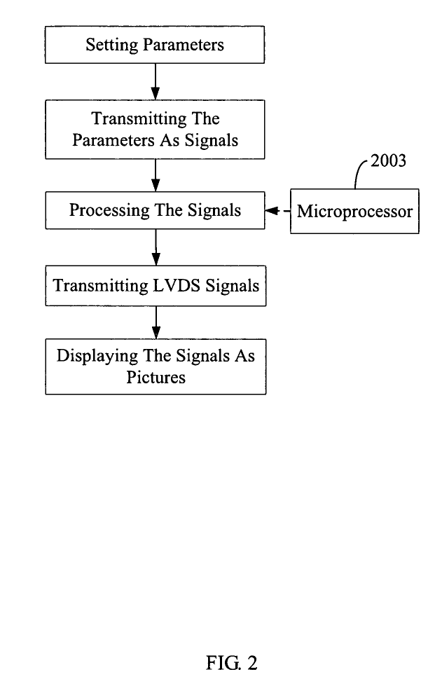

FIG. 2 is a signal flow chart in respect of the system 1. The system 1 is configured for generating pictures, and inspecting the generated pictures. That is, the system 1 calculates corresponding positions and colors of each of pixels and lines that make up each picture, sets corresponding parameters of the pictures such as picture patterns, and sets parameters of the video card 1003 such as picture size, picture color and picture position.

For example, a picture may be provided by a “dot on/off” picture generating system. According to such system, the display panel 201 includes an array of pixels. Each pixel has three dots: red (R), green (G) and blue (B). Any two adjacent dots in the array of pixels are different. The parameters of the pictures as set by the system 1 are transmitted in signal form, and the signals are driven by the video card 1003. Afterward, the signals are transmitted from the first signal port 1004 to the second signal port 2001 via the signal line 30. The microprocessor 2003 controls the scaling chip 2002 to process the signals, and the signals are transmitted to the display panel 201 via low voltage differential signaling (LVDS) or a like signaling standard. Finally, the signals are displayed as pictures on the display panel 201.

The system 1 can directly gather data of the pictures actually displayed on the display panel 201 of the LCD 20, without the need for any viewing of the pictures by an apparatus or a human operator. The system 1 processes and analyzes the data to obtain actual parameters of the pictures actually displayed. Then the system 1 compares the actual parameters with standard benchmark parameters that are stored in the system 1 in advance, and thus determines whether the pictures actually displayed are normal. In general, the standard parameters comply with a corresponding specification in the LCD field that applies to the particular LCD 20 under test. In the preferred embodiment, the system 1 can determine whether the set parameters of the pictures and the video card 1003 are correct and acceptable according to the comparison result. For example, if the actual parameters do not comply with the standard parameters, then the set parameters (of the pictures and/or the video card 1003) are incorrect and unacceptable, and the pictures are considered as abnormal. In contrast, if the actual parameters of the pictures comply with the standard parameters, the set parameters of the pictures and the video card 1003 are correct and acceptable, and the pictures are considered as normal.

In the preferred embodiment, the system 1 can further determine whether the LCD 20 itself has any error, in the case that the actual parameters of the pictures comply with the standard parameters yet the pictures actually displayed on the LCD 20 are still abnormal. Further, the system 1 can display details of the actual parameters on the display panel 201, for a human operator to take note of.

In an alternative embodiment, the system 1 can gather data of the pictures actually displayed on the display panel 201 of the LCD 20 via a camera. The camera captures images of the pictures, and transmits image-data of the pictures to the system 1. In another alternative embodiment, a human operator can observe the pictures actually displayed, and determine whether the pictures are normal.

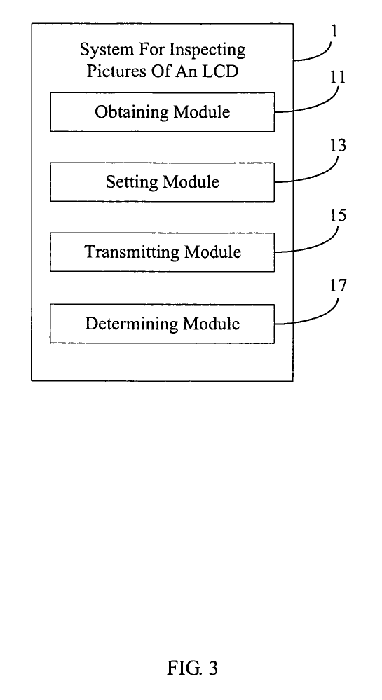

FIG. 3 is a schematic diagram of software function modules of the system 1. The system 1 includes an obtaining module 11, a setting module 13, a transmitting module 15, and a determining module 17.

The obtaining module 11 is configured for obtaining parameters of the host computer 10 and the LCD 20, such as a resolution of the LCD 20. The setting module 13 is configured for setting parameters of the pictures and the video card 1003, and for generating corresponding signals according to the set parameters. The set parameters are used for function inspections of the display panel 201.

The function inspections include inspection of or for geometric figure integrity, white balance setting, afterimage, dot on/off, color filter, shadowing, source integrated circuit (IC), display panel cross talk, determining whether the display panel 201 has defective pixels or other problems when values of RGB in a dot on/off picture generating system are less than 255, determining whether the display panel 201 has flashes when G (green) is set at any selected value, determining whether the display panel 201 has flashes or cross talk problems when the display panel 201 is in one line inversion mode or two line inversion mode, determining whether the display panel 201 has flashes or cross talk problems for each of selected values of RGB in a dot on/off picture generating system, determining whether the display panel 201 has abnormalities during conversion from one picture pattern to another picture pattern, and determining whether the display panel 201 has abnormalities when the LCD 20 is in a power-saving mode.

The parameters of the pictures include picture patterns and other related data. The parameters of the video card 1003 include picture colors, picture sizes, and picture positions. The transmitting module 15 is configured for transmitting the above-described generated signals to the LCD 20. The determining module 17 is configured for gathering data of the pictures actually displayed on the display panel 201, generating actual parameters from gathered data, comparing the actual parameters with standard parameters, and determining whether the set parameters of the pictures and the video card 1003 are correct and acceptable. The determining module 17 is further configured for determining whether the LCD 20 itself has any error, in the case that the actual parameters comply with the standard parameters yet the pictures actually displayed on the LCD 20 are still abnormal.

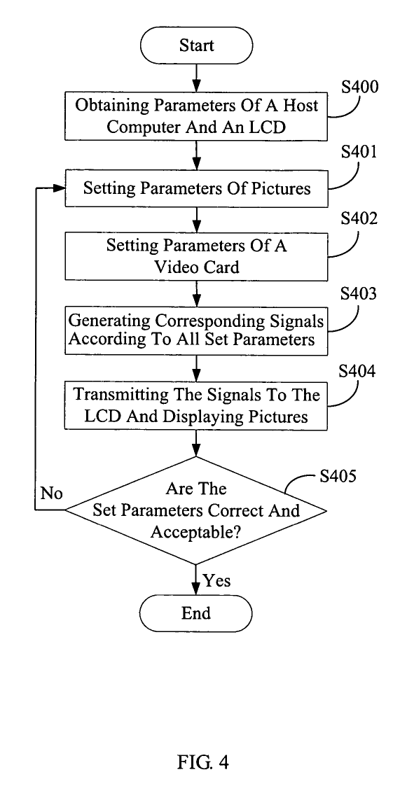

FIG. 4 is a flowchart of a method for inspecting pictures of an LCD in accordance with another preferred embodiment of the present invention. In step S400, the obtaining module 11 obtains the parameters of the host computer 10 and the LCD 20, such as the resolution of the LCD 20.

In step S401, the setting module 13 sets the parameters of the pictures according to the parameters of the host computer 10 and the LCD 20. The parameters of the pictures include picture patterns and other related data.

In step S402, the setting module 13 sets the parameters of the video card 1003. The parameters of the video card 1003 include picture colors, picture sizes, and picture positions.

In step S403, the setting module 13 generates corresponding signals according to all the parameters set by it. The set parameters of the pictures and the video card 1003 are used for function inspections. The function inspections include inspection of or for geometric figure integrity, white balance setting, afterimage, dot on/off, color filter, shadowing, source IC, display panel cross talk, determining whether the display panel 201 has defective pixels or other problems when values of RGB in a dot on/off picture generating system are less than 255, determining whether the display panel 201 has flashes when G (green) is set at any selected value, determining whether the display panel 201 has flashes or cross talk problems when the display panel 201 is in one line inversion mode or two line inversion mode, determining whether the display panel 201 has flashes or cross talk problems for each of selected values of RGB in a dot on/off picture generating system, determining whether the display panel 201 has abnormalities during conversion from one picture pattern to another picture pattern, and determining whether the display panel 201 has abnormalities when the LCD 20 is in a power-saving mode.

In step S404, the transmitting module 15 transmits the signals generated by the setting module 13 to the LCD 20, and the display panel 201 displays corresponding pictures.

In step S405, the determining module 17 gathers data of the pictures displayed on the display panel 201, generates actual parameters of the pictures according to the gathered data, compares the actual parameters of the pictures with standard parameters, and determines whether the set parameters of the pictures and the video card 1003 are correct and acceptable. If the pictures actually displayed are abnormal due to the set parameters being incorrect and/or unacceptable, the process returns to step S401. Then in steps S401 and S402, the respective parameters are set according to, inter alia, the comparison results. In the preferred embodiment, the system 1 can also determine whether the LCD 20 itself has any error, in the case that the actual parameters of the pictures comply with the standard parameters yet the pictures actually displayed on the LCD 20 are still abnormal.

Although the present invention has been specifically described on the basis of preferred embodiments including preferred methods, the invention is not to be construed as being limited thereto. Various changes or modifications may be made to the embodiments and methods without departing from the scope and spirit of the invention.

What is claimed is:

1. A system for inspecting pictures of a liquid crystal display (LCD), the system configured in a host computer that stores standard parameters of pictures for display by the LCD, the system comprising:
a setting module configured for setting one or more parameters of the pictures and a video card, and for generating corresponding signals according to the set parameters, the set parameters being for one or more function inspections of the LCD;
a transmitting module configured for transmitting the signals to the LCD so that the LCD can process the signals and display corresponding pictures; and
a determining module configured for comparing actual parameters of the pictures actually displayed on the LCD with the standard parameters, and for determining whether the set parameters of the pictures and the video card are satisfactory according to a result of the comparison.

2. The system as claimed in claim 1, wherein the host computer comprises:
a central processing unit (CPU) for processing the set parameters and controlling operations of the host computer; and
a video card for controlling conversion from one picture pattern of the LCD to another picture pattern.

3. The system as claimed in claim 1, wherein the signals comprise one or both of sync signals and chrominance signals.

4. The system as claimed in claim 1, wherein the function inspections comprise inspection of or for any one or more items selected from the group consisting of geometric figure integrity, white balance setting, afterimage, dot on/off, color filter, shadowing, source integrated circuit (IC), display panel cross talk, determining whether a display panel of the LCD has defective pixels or other problems when values of RGB in a dot on/off picture generating system are less than 255, determining whether the display panel has flashes when G (green) is set at any selected value, determining whether the display panel has flashes or cross talk problems when the display panel is in one line inversion mode or two line inversion mode, determining whether the display panel has flashes or cross talk problems for each of selected values of RGB in a dot on/off picture generating system, determining whether the display panel has abnormality during conversion from one picture pattern to another picture pattern, and determining whether the display panel has abnormality when the LCD is in a power-saving mode.

5. The system as claimed in claim 1, wherein the set parameters of the video card comprise any one or more items selected from the group consisting of the picture color, picture size, and picture position.

6. The system as claimed in claim 1, wherein the determining module is also configured for directly gathering data of the pictures actually displayed on the LCD, and processing the gathered data to obtain the actual parameters.

7. A computer-based method for inspecting pictures of a liquid crystal display (LCD), comprising:
storing standard parameters of pictures for display by the LCD;
setting one or more parameters of pictures for display by the LCD;
setting one or more parameters of a video card;
generating corresponding signals according to all the set parameters;
transmitting the signals to the LCD so that the LCD can display corresponding pictures;
generating actual parameters of the pictures actually displayed on the LCD;
comparing the actual parameters of the pictures with the standard parameters; and
determining whether the set parameters of the pictures are satisfactory according to the comparison result.

8. The method as claimed in claim 7, wherein the set parameters are for one or more function inspections of the LCD, and the function inspections comprise inspection of or for any one or more items selected from the group consisting of geometric figure integrity, white balance setting, afterimage, dot on/off, color filter, shadowing, source integrated circuit (IC), display panel cross talk, determining whether a display panel of the LCD has defective pixels or other problems when values of RGB in a dot on/off picture generating system are less than 255, determining whether the display panel has flashes when G (green) is set at any selected value, determining whether the display panel has flashes or cross talk problems when the display panel is in one line inversion mode or two line inversion mode, determining whether the display panel has flashes or cross talk problems for each of selected values of RGB in a dot on/off picture generating system, determining whether the display panel has abnormality during conversion from one picture pattern to another picture pattern, and determining whether the display panel has abnormality when the LCD is in a power-saving mode.

9. The method as claimed in claim 7, wherein the set parameters of the video card comprise any one or more items selected from the group consisting of picture color, picture size, and picture position.

10. The method as claimed in claim 7, further comprising returning to setting one or more parameters of pictures for display by the LCD and setting one or more parameters of the video card, if the parameters of the pictures are not satisfactory.

11. The method as claimed in claim 7, further comprising directly gathering data of the pictures actually displayed on the LCD, and processing the gathered data to generate the actual parameters.

12. A computer-based method for inspecting pictures of a liquid crystal display (LCD), comprising:
storing standard parameters of pictures for display by the LCD;
setting one or more parameters of pictures for display by the LCD;
generating corresponding signals according to all the set parameters;
transmitting the signals to the LCD so that the LCD can display corresponding pictures;
generating actual parameters of the pictures actually displayed on the LCD;
comparing the actual parameters of the pictures with the standard parameters; and
determining whether the set parameters of the pictures are satisfactory according to the comparison result.
